(19) United States
(12) Patent Application Publication
(10) Pub. No.: US 2026/0144039 A1
(43) Pub. Date: May 21, 2026

(54) POWER MODULE

(71) Applicant: SHINKO ELECTRIC INDUSTRIES CO., LTD., Nagano (JP)

(72) Inventor: Koji BANDO, Nagano (JP)

(21) Appl. No.: 19/391,069

(22) Filed: Nov. 17, 2025

(30) Foreign Application Priority Data
Nov. 21, 2024 (JP) 2024-202964

(51) Int. Cl. H01L 23/482; H01L 23/00; H01L 23/34; H01L 25/07

(52) U.S. Cl. CPC H10W 20/40; H10W 40/00; H10W 90/00; H10W 72/07653; H10W 90/763

(57) ABSTRACT

A power module includes a first device having first and second surfaces provided with first and second electrodes, respectively, a second device having third and fourth surfaces provided with third and fourth electrodes, respectively, a first insulating base having a fifth surface bonded with the first and second devices and a sixth surface opposite to the fifth surface, a first conductor penetrating the first insulating base, coupled to the first electrode and stacked on the sixth surface, a second conductor penetrating the first insulating base, coupled to the third electrode and stacked on the sixth surface, third and fourth conductors coupled to the second and fourth electrodes, respectively, a fifth conductor coupling the first and fourth conductors, first and second terminals coupled to the third and second conductors, respectively, and an insulating film provided between the first and second terminals and having surfaces facing the first and second terminals, respectively.

### CROSS-REFERENCE TO RELATED APPLICATIONS

This application is based upon and claims priority to Japanese Patent Application No. 2024-202964, filed on November 21, 2024, the entire contents of which are incorporated herein by reference.

### FIELD

Certain aspects of the embodiments discussed herein are related to power modules.

### BACKGROUND

There is a proposed power module having a P terminal and an N terminal that overlap each other in a plan view.

Related art include Japanese Laid-Open Patent Publication No. 2017-005241, Japanese Laid-Open Patent Publication No. 2002-252327, and International Publication Pamphlet No. WO 2024/202838, for example.

In recent years, there are increased demands to miniaturize the power module.

### SUMMARY

Accordingly, it is an object in one aspect of the embodiments of the present disclosure to provide a power module that can be miniaturized.

According to one aspect of the embodiments of the present disclosure, a power module includes a first semiconductor device having a first surface and a second surface opposite to the first surface, a first electrode provided on the first surface, and a second electrode provided on the second surface; a second semiconductor device having a third surface and a fourth surface opposite to the third surface, a third electrode provided on the third surface, and a fourth electrode provided on the fourth surface; a first insulating base material having a fifth surface to which the first semiconductor device and the second semiconductor device are bonded, and a sixth surface opposite to the fifth surface; a first conductive member penetrating the first insulating base material, electrically connected to the first electrode, and stacked on the sixth surface of the first insulating base material; a second conductive member penetrating the first insulating base material, electrically connected to the third electrode, and stacked on the sixth surface of the first insulating base material; a third conductive member electrically connected to the second electrode; a fourth conductive member electrically connected to the fourth electrode; a fifth conductive member electrically connecting the first conductive member and the fourth conductive member; a first terminal electrically connected to the third conductive member; a second terminal electrically connected to the second conductive member; and an insulating film having a seventh surface facing the first terminal and an eighth surface facing the second terminal, wherein the insulating film is provided between the first terminal and the second terminal.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a perspective view (part 1) illustrating a power module according to a first embodiment;

FIG. 2 is a perspective view (part 2) illustrating the power module according to the first embodiment;

FIG. 3 is a front view illustrating a part of the power module according to the first embodiment;

FIG. 4 is a perspective view (part 1) illustrating a part of the power module according to the first embodiment;

FIG. 5 is a perspective view (part 2) illustrating a part of the power module according to the first embodiment;

FIG. 6 is a perspective view (part 3) illustrating a part of the power module according to the first embodiment;

FIG. 7 is a perspective view (part 4) illustrating a part of the power module according to the first embodiment;

FIG. 8 is a perspective view (part 5) illustrating a part of the power module according to the first embodiment;

FIG. 9 is a cross sectional view schematically illustrating the power module according to the first embodiment;

FIG. 10 is a cross sectional view schematically illustrating a part of the power module according to the first embodiment;

FIG. 11 is a top view schematically illustrating a part of the power module according to the first embodiment;

FIG. 12 is a circuit diagram illustrating the power module according to the first embodiment;

FIG. 13 is a perspective view (part 1) illustrating the power module according to a second embodiment;

FIG. 14 is a perspective view (part 2) illustrating the power module according to the second embodiment;

FIG. 15 is a perspective view (part 1) illustrating a part of the power module according to the second embodiment;

FIG. 16 is a perspective view (part 2) illustrating a part of the power module according to the second embodiment; and

FIG. 17 is a cross sectional view schematically illustrating a part of the power module according to the second embodiment.

### DESCRIPTION OF EMBODIMENTS

Hereinafter, embodiments will be described in detail with reference to the accompanying drawings. In the present specification and the drawings, constituent elements having substantially the same functional configuration are designated by the same reference numerals, and a redundant description thereof may be omitted. Further, in the present disclosure, an X-axis (X1-X2 direction), a Y-axis (Y1-Y2 direction), and a Z-axis (Z1-Z2 direction) are mutually orthogonal directions. A plane including the X-axis and the Y-axis is referred to as an XY-plane, a plane including the Y-axis and the Z-axis is referred to as a YZ-plane, and a plane including the Z-axis and the X-axis is referred to as a ZX-plane. For the sake of convenience, the Z1-Z2 direction is defined as a vertical direction (or up-down direction, a Z1-side is defined as an upper side, and a Z2-side is defined as a lower side. Moreover, a plan view refers to a view of an object viewed from the Z1-side, and a planar shape refers to a shape of the object in the plan view viewed from the Z1-side. However, the power module may be used in an upside-down state or may be disposed at an arbitrary angle.

### First Embodiment

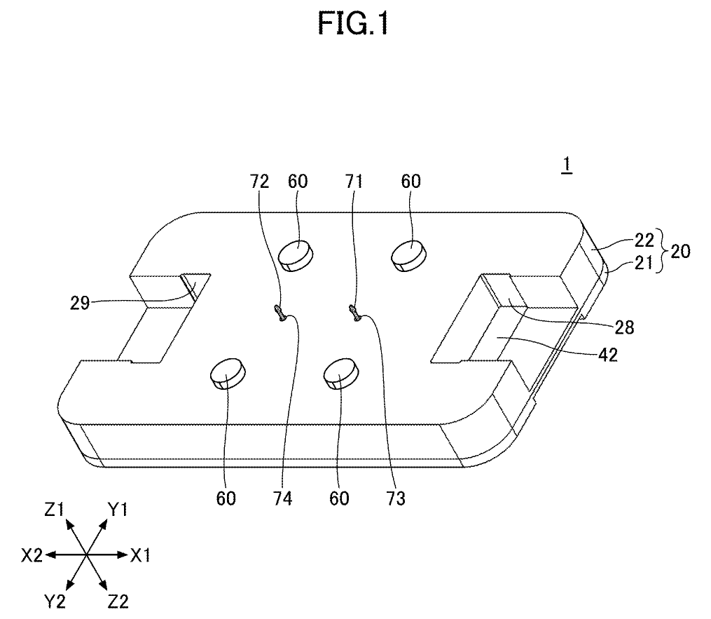

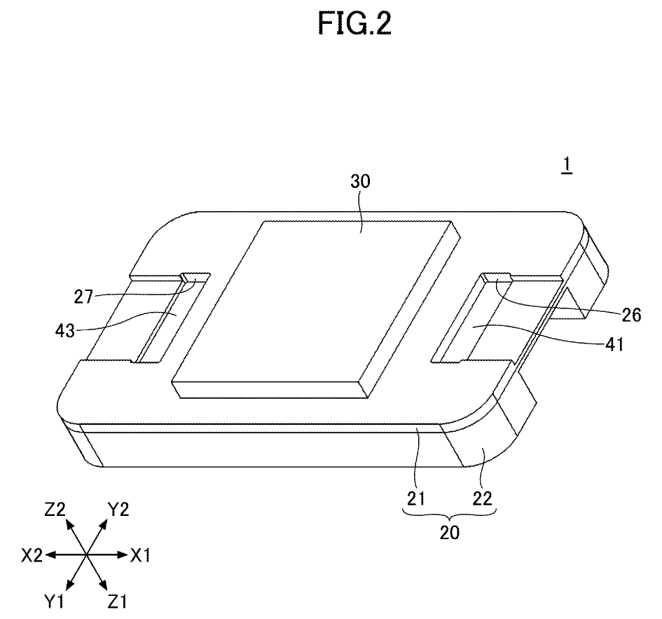

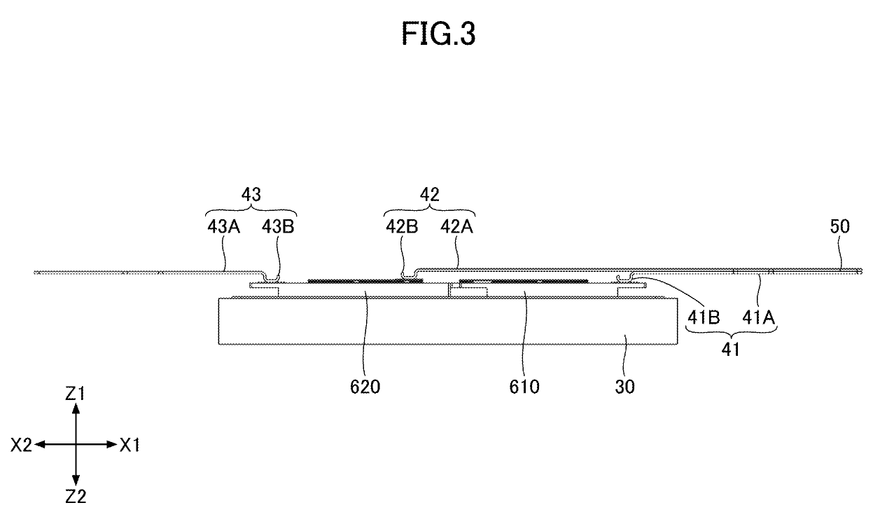

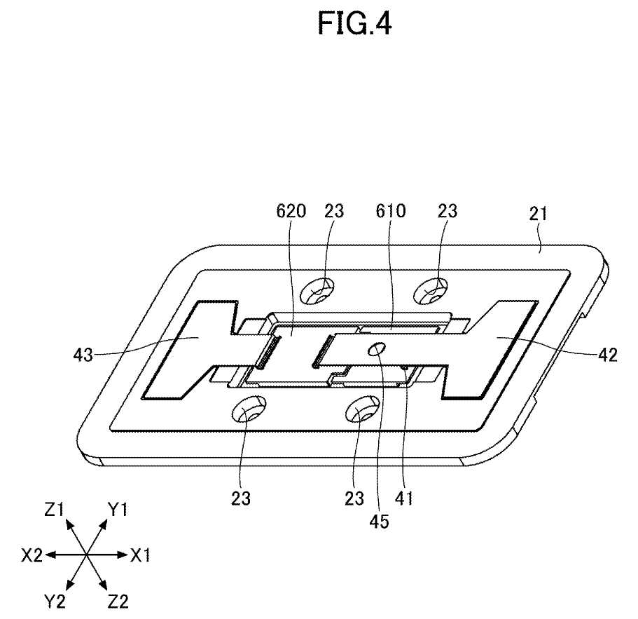

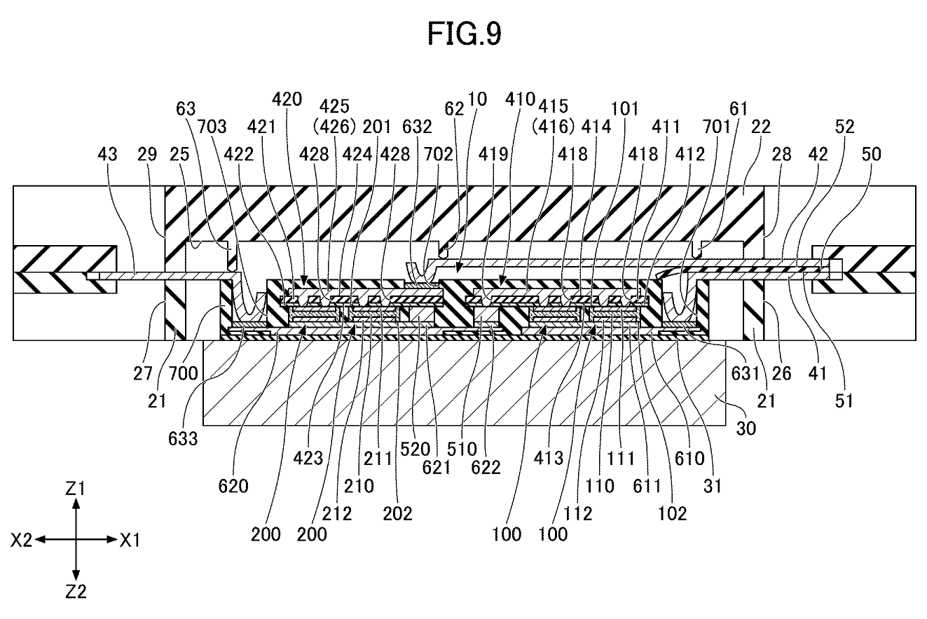

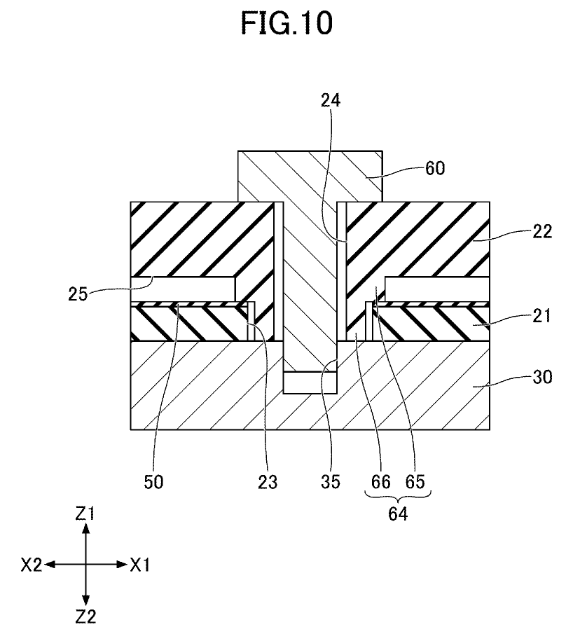

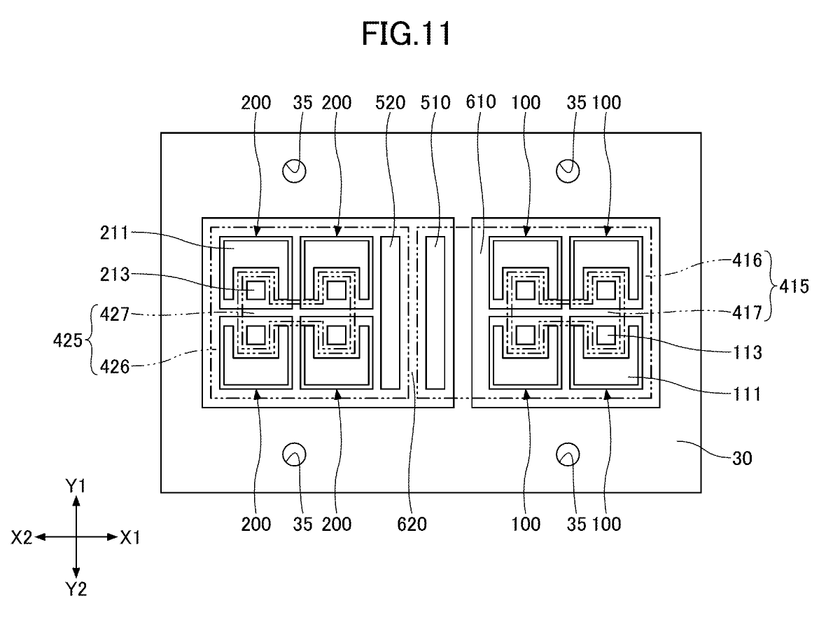

A first embodiment will be described. A first embodiment relates to a power module. FIG. 1 and FIG. 2 are perspective views illustrating the power module according to the first embodiment. FIG. 3 is a front view illustrating a part of the power module according to the first embodiment. FIG. 4 through FIG. 8 are perspective views illustrating parts of the power module according to the first embodiment. FIG. 9 is a cross sectional view schematically illustrating the power module according to the first embodiment. FIG. 10 is a cross sectional view schematically illustrating a part of the power module according to the first embodiment. FIG. 11 is a top view schematically illustrating a part of the power module according to the first embodiment.

As illustrated in FIG. 1 through FIG. 11, a power module 1 according to the first embodiment includes a semiconductor package 10, a housing 20, a heat sink 30, an external terminal 41, an external terminal 42, an external terminal 43, an insulating film 50, and four male screws 60.

As illustrated in FIG. 1, FIG. 9, and FIG. 11, the semiconductor package 10 includes four semiconductor devices 100, four semiconductor devices 200, a flexible wiring board 410, a flexible wiring board 420, a shim 510, a shim 520, a lead terminal 610, a lead terminal 620, a control terminal 71, a control terminal 72, and a mold 700.

The semiconductor devices 100 and 200 are formed using silicon (Si) or silicon carbide (SiC), for example. The semiconductor devices 100 and 200 may be formed using gallium nitride (GaN) or gallium arsenide (GaAs). For example, the semiconductor devices 100 and 200 may be insulated gate bipolar transistors (IGBTs) or metal oxide semiconductor field effect transistors (MOSFETs). Planar shapes of the semiconductor devices 100 and 200 are rectangular shapes, for example. Thicknesses of the semiconductor devices 100 and 200 are approximately 50 μm to approximately 500 μm, for example.

As illustrated in FIG. 9, the semiconductor device 100 has a first surface 101 and a second surface 102 opposite to the first surface 101. In addition, the semiconductor device 100 includes a main body 110, an electrode 111, an electrode 112, and an electrode 113. The electrode 111 and the electrode 113 are provided on the first surface 101, and the electrode 112 is provided on the second surface 102. For example, the electrode 111, the electrode 112, and the electrode 113 are a source electrode, a drain electrode, and a gate electrode, respectively. The semiconductor device 100 is an example of a first semiconductor device, the first surface 101 is an example of a first surface, and the second surface 102 is an example of a second surface. The electrode 111 is an example of a first electrode, and the electrode 112 is an example of a second electrode.

As illustrated in FIG. 9, the semiconductor device 200 has a first surface 201 and a second surface 202 opposite to the first surface 201. In addition, the semiconductor device 200 includes a main body 210, an electrode 211, an electrode 212, and an electrode 213. The electrode 211 and the electrode 213 are provided on the first surface 201, and the electrode 212 is provided on the second surface 202. For example, the electrode 211, the electrode 212, and the electrode 213 are a source electrode, a drain electrode, and a gate electrode, respectively. The semiconductor device 200 is an example of a second semiconductor device, the first surface 201 is an example of a third surface, and the second surface 202 is an example of a fourth surface. The electrode 211 is an example of a third electrode, and the electrode 212 is an example of a fourth electrode.

A material used for the electrode 111, the electrode 112, the electrode 113, the electrode 211, the electrode 212, and the electrode 213 (hereinafter also collectively referred to as "electrodes") may be a metal such as aluminum (Al), copper (Cu), or the like, or an alloy including at least one kind of metal selected from these kinds of metals, for example. A surface treatment layer may be formed on a surface of the electrode, as necessary. Examples of the surface treatment layer include a gold (Au) layer, a nickel (Ni) layer/Au layer (a metal layer in which a Ni layer and a Au layer are stacked in this order), a Ni layer/palladium (Pd) layer/Au layer (a metal layer in which a Ni layer, a Pd layer, and an Au layer are stacked in this order), or the like. A metal layer (electroless plating metal layer) formed by an electroless plating method, for example, can be used for the Au layer, the Ni layer, and the Pd layer. Further, the Au layer is a metal layer made of Au or an Au alloy, the Ni layer is a metal layer made of Ni or an Ni alloy, and the Pd layer is a metal layer made of Pd or a Pd alloy.

The shims 510 and 520 are metal plates, such as Cu plates or the like. Thicknesses of the shims 510 and 520 are approximately the same as the thicknesses of the semiconductor devices 100 and 200, respectively.

The flexible wiring board 410 includes an insulating base material 411, an insulating adhesive layer 412, and an interconnect layer 415. The insulating base material 411 has a first surface 413 and a second surface 414 opposite to the first surface 413. The insulating adhesive layer 412 is provided on the first surface 413, and the interconnect layer 415 is provided on the second surface 414. The insulating adhesive layer 412 may be provided on the entire first surface 413. The interconnect layer 415 is stacked on the second surface 414. The insulating base material 411 is an example of a second insulating base material. The first surface 413 is an example of a ninth surface, and the second surface 414 is an example of a tenth surface.

The insulating base material 411 is a resin film, for example. Examples of a resin material used for the resin film include an insulating resin, such as a polyimide-based resin, a polyethylene-based resin, an epoxy-based resin, or the like. The insulating base material 411 has flexibility, for example. The flexibility of the material refers to a property that allows the material to be bent or deflected. A planar shape of the insulating base material 411 is a rectangular shape, for example. A thickness of the insulating base material 411 is approximately 50 μm to approximately 100 μm, for example.

The four semiconductor devices 100 and the shim 510 are bonded to the first surface 413 of the insulating base material 411 by the insulating adhesive layer 412. The first surface 101 of the semiconductor device 100 faces the first surface 413 of the insulating base material 411. A through hole 418 reaching the electrode 111, a through hole 419 reaching the shim 510, and a through hole (not illustrated) reaching the electrode 113 are formed in the insulating base material 411 and the insulating adhesive layer 412. A plurality of through holes 418 may be formed. A plurality of through holes 419 may be formed. The shim 510 is an example of a fifth conductive member.

A material used for the insulating adhesive layer 412 may be an epoxy-based adhesive, a polyimide-based adhesive, a silicone-based adhesive, or the like, for example. A thickness of the insulating adhesive layer 412 is approximately 20 μm to approximately 40 μm, for example.

As illustrated in FIG. 9 and FIG. 11, the interconnect layer 415 includes an interconnect 416 connected to the electrode 111 via the through hole 418, and an interconnect 417 connected to the electrode 113 via the through hole (not illustrated). The interconnect 416 is also connected to the shim 510 via the through hole 419. The interconnect 416 is an example of a first conductive member.

The interconnect 416 includes a via interconnect filling an inside of the through hole 418, a via interconnect filling an inside of the through hole 419, and an interconnect pattern formed on the second surface 414 of the insulating base material 411. The interconnect 417 includes a via interconnect filling an inside of the through hole (not illustrated), and an interconnect pattern formed on the second surface 414 of the insulating base material 411.

The flexible wiring board 420 includes an insulating base material 421, an insulating adhesive layer 422, and an interconnect layer 425. The insulating base material 421 has a first surface 423 and a second surface 424 opposite to the first surface 423. The insulating adhesive layer 422 is provided on the first surface 423, and the interconnect layer 425 is provided on the second surface 424. The insulating adhesive layer 422 may be provided on the entire first surface 423. The interconnect layer 425 is stacked on the second surface 424. The insulating base material 421 is an example of a third insulating base material. The first surface 423 is an example of an eleventh surface, and the second surface 424 is an example of a twelfth surface.

The four semiconductor devices 200 and the shim 520 are bonded to the first surface 423 of the insulating base material 421 by the insulating adhesive layer 422. The first surface 201 of the semiconductor device 200 faces the first surface 423 of the insulating base material 421. A through hole 428 reaching the electrode 211 and a through hole (not illustrated) reaching the electrode 213 are formed in the insulating base material 421 and the insulating adhesive layer 422. A plurality of through holes 428 may be formed.

A material used for and a thickness of the insulating base material 421 are the same as the material used for and the thickness of the insulating base material 411, for example. A material used for and a thickness of the insulating adhesive layer 422 are the same as the material used for and the thickness of the insulating adhesive layer 412, for example.

As illustrated in FIG. 9 and FIG. 11, the interconnect layer 425 includes an interconnect 426 connected to the electrode 211 via the through hole 428, and an interconnect 427 connected to the electrode 213 via the through hole (not illustrated). The interconnect 426 and the shim 520 are electrically insulated from each other. The interconnect 426 is an example of a second conductive member.

The interconnect 426 includes a via interconnect filling an inside of the through hole 428, and an interconnect pattern formed on the second surface 424 of the insulating base material 421. The interconnect 427 includes a via interconnect filling an inside of the through hole (not illustrated), and an interconnect pattern formed on the second surface 424 of the insulating base material 421.

The lead terminal 610 is bonded to the electrode 112 of the semiconductor device 100 by a conductive adhesive layer 611. The lead terminal 620 is bonded to the electrode 212 of the semiconductor device 200 by a conductive adhesive layer 621. The shim 520 is also bonded to the lead terminal 620 by the conductive adhesive layer 621. The shim 510 is bonded to lead terminal 620 by a conductive adhesive layer 622. The lead terminals 610 and 620 are formed of a lead frame made of Cu, for example. The conductive adhesive layers 611, 621, and 622 are solder layers or sintered metal layers, for example. The conductive adhesive layers 611, 621, and 622 may be made of a conductive paste. The lead terminal 610 is an example of a third conductive member, and the lead terminal 620 is an example of a fourth conductive member.

The mold 700 encapsulates the semiconductor device 100, the semiconductor device 200, the flexible wiring board 410, the flexible wiring board 420, the shim 510, the shim 520, the lead terminal 610, and the lead terminal 620. A lower surface (a surface on the Z2-side) of the lead terminal 610 and a lower surface (a surface on the Z2-side) of the lead terminal 620 are exposed from the mold 700. The mold 700 has an opening 701 reaching an upper surface (a surface on the Z1-side) of the lead terminal 610, an opening 702 reaching an upper surface (a surface on the Z1-side) of the interconnect 426, and an opening 703 reaching an upper surface (a surface on the Z1-side) of the lead terminal 620.

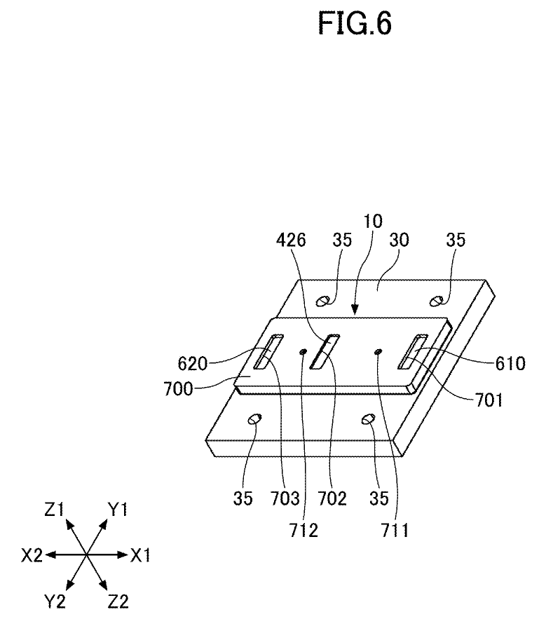

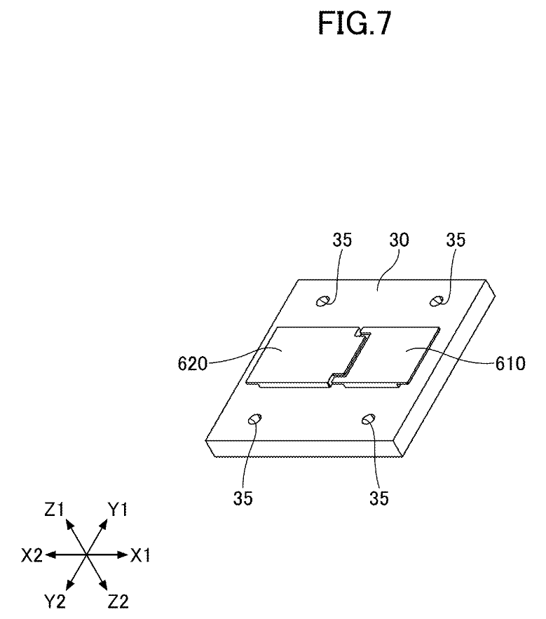

As illustrated in FIG. 6 and FIG. 9, the semiconductor package 10 is provided on the heat sink 30. As illustrated in FIG. 7 and FIG. 9, the semiconductor devices 100 and 200 are mounted on the heat sink 30. A thermal interface material (TIM) 31 is provided between the semiconductor package 10 and the heat sink 30. The TIM 31 is in contact with the lead terminals 610 and 620 and the heat sink 30.

As illustrated in FIG. 6, FIG. 7, and FIG. 10, four holes 35 to be inserted with the male screws 60 are formed in an upper surface of the heat sink 30. A female thread is formed on a wall surface defining each of the holes 35. In the plan view, one hole 35 is formed on the Y1-side of the lead terminal 610, one hole 35 is formed on the Y2-side of the lead terminal 610, one hole 35 is formed on the Y1-side of the lead terminal 620, and one hole 35 is formed on the Y2-side of the lead terminal 620. The heat sink 30 is an example of a heat dissipation member.

The housing 20 includes a lower case 21 and an upper case 22. The housing 20 is provided on the heat sink 30, and is configured to house (or accommodate) the semiconductor devices 100 and 200 and fix the external terminals 41, 42, and 43. The lower case 21 is provided on the heat sink 30, and surrounds the semiconductor package 10 in the plan view. The upper case 22 is provided on the lower case 21. The lower case 21 is an example of a first case, and the upper case 22 is an example of a second case.

For example, the external terminal 41 and the external terminal 42 are formed of metal plates, respectively. As illustrated in FIG. 3 and FIG. 9, the insulating film 50 is provided between the external terminal 41 and the external terminal 42. The insulating film 50 has a first surface 51 facing the external terminal 41, and a second surface 52 opposite to the first surface 51 and facing the external terminal 42. For example, the external terminal 41 is in contact with the first surface 51 of the insulating film 50, and the external terminal 42 is in contact with the second surface 52 of the insulating film 50. A material used for the insulating film 50 is polyimide, for example. The first surface 51 is an example of a seventh surface, and the second surface 52 is an example of an eighth surface.

As illustrated in FIG. 3, the external terminal 41 has a flat plate portion 41A and a curved portion 41B. The flat plate portion 41A has the Z-axis direction as a thickness direction thereof, and extends along the X-axis. The curved portion 41B is continuous with an end portion on the X2-side of the flat plate portion 41A, and protrudes toward the Z2-side. For example, in a cross sectional view perpendicular to the Y-axis, the curved portion 41B has a substantially U-shape or a substantially J-shape. The external terminal 42 has a flat plate portion 42A and a curved portion 42B. The flat plate portion 42A has the Z-axis direction as a thickness direction thereof, and extends along the X-axis. The curved portion 42B is continuous with an end portion on the X2-side of the flat plate portion 42A, and protrudes toward the Z2-side. For example, in a cross sectional view perpendicular to the Y-axis, the curved portion 42B has a substantially U-shape or a substantially J-shape. The external terminal 41 is an example of a first terminal, and the external terminal 42 is an example of a second terminal.

The insulating film 50 is provided between the external terminal 41 and the flat plate portion 42A. A stack composed of the flat plate portion 41A, the insulating film 50, and the flat plate portion 42A is disposed on the lower case 21. The external terminal 41 is disposed on the lower case 21, the insulating film 50 is disposed on the external terminal 41, and the external terminal 42 is disposed on the insulating film 50.

The curved portion 41B enters inside the opening 701, and is bonded to the lead terminal 610 by the conductive adhesive layer 631. The curved portion 42B enters inside of the opening 702, and is bonded to the interconnect 426 by the conductive adhesive layer 632. The insulating film 50 covers the opening 701, and extends to the X2-side than the end portion on the X2-side of the opening 701.

The external terminal 43 is formed of a metal plate, for example. The external terminal 43 has a flat plate portion 43A and a curved portion 43B. The flat plate portion 43A has the Z-axis direction as a thickness direction thereof, and extends along the X-axis. The curved portion 43B is continuous with an end portion on the X1-side of the flat plate portion 43A, and protrudes toward the Z2-side. For example, in a cross sectional view perpendicular to the Y-axis, the flat plate portion 43A has a substantially U-shape or a substantially J-shape. The external terminal 43 is an example of a third terminal.

The flat plate portion 43A is disposed on the lower case 21. The curved portion 43B enters inside the opening 703, and is bonded to the lead terminal 620 by the conductive adhesive layer 633.

The insulating film 50 may have a portion separated from the external terminals 41 and 42. For example, the insulating film 50 may have a portion located at a position on the lower case 21 separated from the external terminals 41 and 42, or may have a portion located at a position on the external terminal 43 separated from the external terminals 41 and 42.

The upper case 22 covers the semiconductor package 10, the external terminals 41, 42, and 43, and the insulating film 50. The end portion on the X1-side of the external terminal 41 and the end portion on the X1-side of the external terminal 42 are sandwiched between the upper case 22 and the lower case 21 and fixed to the upper case 22 and the lower case 21. On the other hand, the end portion on the X2-side of the external terminal 41 and the end portion on the X2-side of the external terminal 42 are not fixed to the upper case 22 and the lower case 21. Accordingly, each of the external terminals 41 and 42 has a fixed end and a free end like a cantilever. In addition, the end portion on the X2-side of the external terminal 43 is sandwiched between the upper case 22 and the lower case 21 and fixed to the upper case 22 and the lower case 21. On the other hand, the end portion on the X1-side of the external terminal 43 is not fixed to the upper case 22 and the lower case 21. That is, the external terminal 43 also has a fixed end and a free end like a cantilever.

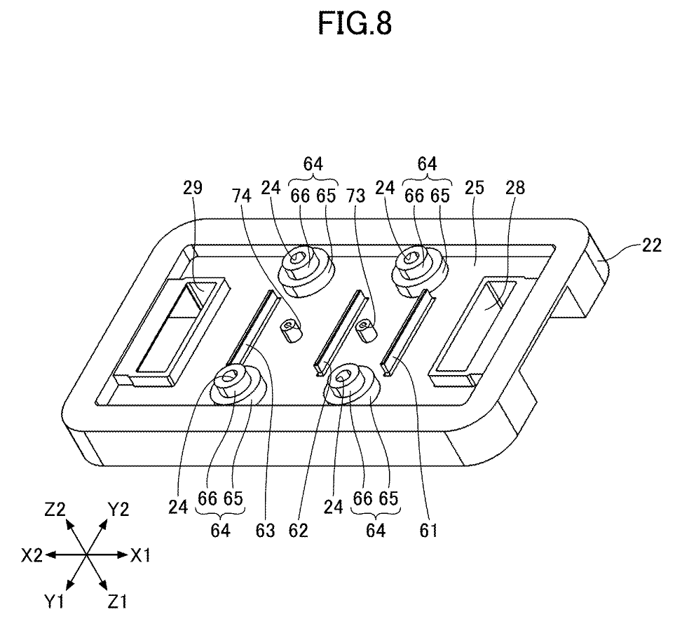

As illustrated in FIG. 8, FIG. 9, and FIG. 10, the upper case 22 has a surface 25 facing the lower case 21, and protrusions 61, 62, 63, and 64 protruding from the surface 25 toward the Z2-side.

The protrusions 61, 62, and 63 have rectangular plate shapes and extend along the Y-axis, respectively. The protrusion 63 is located on the X2-side of the protrusion 62, and the protrusion 62 is located on the X2-side of the protrusion 61. The protrusion 61 makes contact with the flat plate portion 42A near the curved portion 41B, and presses the curved portion 41B toward the lead terminal 610. The protrusion 62 makes contact with the flat plate portion 42A near the curved portion 42B, and presses the curved portion 42B toward the interconnect 426. The protrusion 63 makes contact with the flat plate portion 43A near the curved portion 43B, and presses the curved portion 43B toward the lead terminal 620.

The upper case 22 has four protrusions 64. The protrusion 64 includes a protruding portion 65 having a cylindrical shape and protruding from the surface 25 toward the Z2-side, and a protruding portion 66 having a cylindrical shape and protruding from the protruding portion 65 toward the Z2-side. The protrusions 64 overlap the holes 35 formed in the heat sink 30 in the plan view. For example, center axes of the protruding portions 65 and 66 and the hole 35 coincide with one another. A diameter of the protruding portion 66 is smaller than a diameter of the protruding portion 65 in the plan view.

As illustrated in FIG. 1, FIG. 2, FIG. 8, and FIG. 9, the lower case 21 is formed with an opening 26 reaching a lower surface of the external terminal 41, and an opening 27 reaching a lower surface of the external terminal 43. Further, the upper case 22 is formed with an opening 28 reaching an upper surface of the external terminal 42, and an opening 29 reaching an upper surface of the external terminal 43.

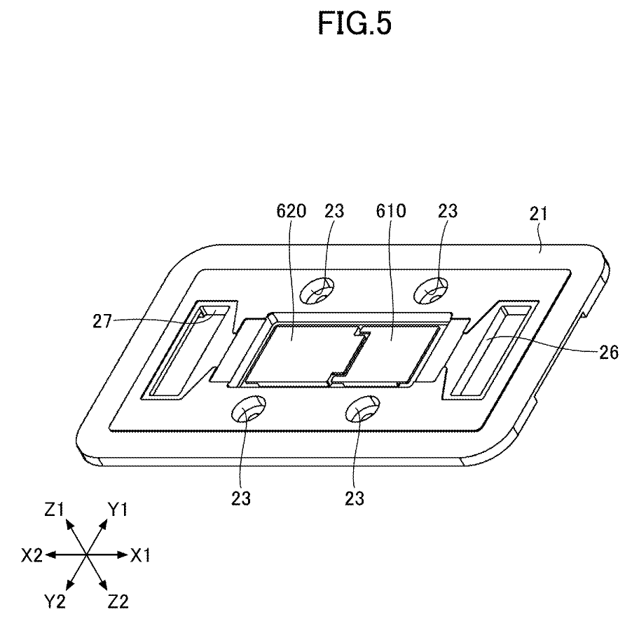

As illustrated in FIG. 4, FIG. 5, and FIG. 10, the lower case 21 has through holes 23 through which the male screws 60 penetrate. As illustrated in FIG. 8 and FIG. 10, the upper case 22 is formed with through holes 24 through which the male screws 60 penetrate. The through hole 24 penetrates the protrusion 64. The through holes 23 and 24 connect to the hole 35 formed in the heat sink 30. For example, a diameter of the through hole 24 is larger than a diameter of the hole 35, and a diameter of the through hole 23 is larger than the diameter of the through hole 24. The protruding portion 66 is inserted into the through hole 23. The through holes 24 and 23 overlap the hole 35 in the plan view. For example, center axes of the through holes 24 and 23 and the hole 35 coincide with one another.

The male screw 60 penetrates the through holes 24 and 23 and is screwed into the hole 35. As illustrated in FIG. 10, the protruding portion 66 is provided between the male screw 60 and an inner wall surface of the through hole 23. A head of the male screw 60 is in contact with an upper surface of the upper case 22. The male screw 60 presses the upper case 22 toward the heat sink 30, and fastens the housing 20 toward the heat sink 30. The male screw 60 is a bolt, for example. The male screw 60 is an example of a fastening member.

The control terminal 71 is bonded to the interconnect 417 by a conductive adhesive layer (not illustrated), and the control terminal 72 is bonded to the interconnect 427 by a conductive adhesive layer (not illustrated). As illustrated in FIG. 4, the external terminal 42 is formed with a through hole 45 to be penetrated by the control terminal 71. In addition, as illustrated in FIG. 6, the mold 700 is formed with a through hole 711 to be penetrated by the control terminal 71, and a through hole 712 to be penetrated by the control terminal 72. As illustrated in FIG. 1 and FIG. 8, the upper case 22 is formed with a through hole 73 to be penetrated by the control terminal 71, and a through hole 74 to be penetrated by the control terminal 72. The control terminal 71 penetrates the through holes 45, 711, and 73 along the Z-axis on the interconnect 417, and extends to an outside of the upper case 22. The control terminal 72 penetrates the through holes 712 and 74 along the Z-axis on the interconnect 427, and extends to the outside of the upper case 22.

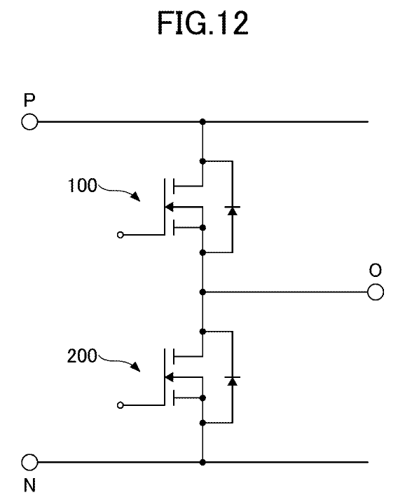

Next, a circuit configuration of the power module 1 according to the first embodiment will be described. FIG. 12 is a circuit diagram illustrating the power module according to the first embodiment. Although one semiconductor device 100 of the four semiconductor devices 100 and one semiconductor device 200 of the four semiconductor devices 200 are illustrated in FIG. 12 for the sake of convenience, the four semiconductor devices 100 are mutually connected in parallel, and the four semiconductor devices 200 are mutually connected in parallel. The power module 1 includes a half-bridge circuit illustrated in FIG. 12.

As illustrated in FIG. 12, the electrode 112 of the semiconductor device 100 is electrically connected to the external terminal 41 as the P terminal, via the lead terminal 610. The electrode 211 of the semiconductor device 200 is electrically connected to the external terminal 42 as the N terminal, via the interconnect 426. In addition, the electrode 111 of the semiconductor device 100 is electrically connected to the external terminal 43 as an O terminal, via the interconnect 416, the shim 510, and the lead terminal 620. Further, the electrode 212 of the semiconductor device 200 is electrically connected to the external terminal 43 as the O terminal, via the lead terminal 620. The P terminal is an input terminal on a positive electrode side, the N terminal is an input terminal on a negative electrode side, and the O terminal is an output terminal. Accordingly, currents flow through the external terminal 41 and the external terminal 42 in opposite directions.

Moreover, the electrode 113 of the semiconductor device 100 is electrically connected to the control terminal 71 via the interconnect 417, and the electrode 213 of the semiconductor device 200 is electrically connected to the control terminal 72 via the interconnect 427. Hence, a control signal from the control terminal 71 is input to the electrode 113 of the semiconductor device 100, and a control signal from the control terminal 72 is input to the electrode 213 of the semiconductor device 200.

Next, a method for manufacturing the power module according to the first embodiment will be described.

First, the semiconductor package 10, the lower case 21, the upper case 22, the heat sink 30, the external terminal 41, the external terminal 42, the external terminal 43, the insulating film 50, and the four male screws 60 are prepared.

Next, the semiconductor package 10 is provided on the heat sink 30 via the TIM 31. Thereafter, the lower case 21 is provided on the heat sink 30. Subsequently, while the external terminals 41 and 43 are provided on the lower case 21, the curved portion 41B is bonded to the lead terminal 610 by the conductive adhesive layer 631, and the curved portion 43B is bonded to the lead terminal 620 by the conductive adhesive layer 633. Next, the insulating film 50 is provided on the external terminal 41. Thereafter, the external terminal 42 is provided on the insulating film 50, and the curved portion 42B is bonded to the interconnect 426 by the conductive adhesive layer 632.

Subsequently, the upper case 22 is provided on the lower case 21, and the male screws 60 are screwed into the holes 35. As a result, the male screws 60 press the upper case 22 toward the heat sink 30, and a stack of the flat plate portion 41A, the insulating film 50, and the flat plate portion 42A is sandwiched between the upper case 22 and the lower case 21. The flat plate portion 43A is also sandwiched between the upper case 22 and the lower case 21.

As described above, in the power module 1, the semiconductor device 100 is bonded to the first surface 413 of the insulating base material 411, the interconnect 416 is stacked on the second surface 414 of the insulating base material 411, the electrode 111 of the semiconductor device 100 is electrically connected to the interconnect 416, and the electrode 112 of the semiconductor device 100 is electrically connected to the lead terminal 610. The semiconductor device 200 is bonded to the first surface 423 of the insulating base material 421, the interconnect 426 is stacked on the second surface 424 of the insulating base material 421, the electrode 211 of the semiconductor device 200 is electrically connected to the interconnect 426, and the electrode 212 of the semiconductor device 200 is electrically connected to the lead terminal 620. The interconnect 416 and the lead terminal 620 are electrically connected to each other via the shim 510. The half-bridge circuit is configured in this manner. The insulating film 50 is provided between the external terminal 41 electrically connected to the lead terminal 610 and the external terminal 42 electrically connected to the interconnect 426. For this reason, the semiconductor package 10 including the half-bridge circuit can be miniaturized, and areas occupied by the external terminals 41 and 42 can be reduced when compared to a configuration in which the external terminals 41 and 42 are arranged side by side in the plan view. Accordingly, according to the first embodiment, a compact power module 1 can be obtained. In addition, even if the areas of the external terminals 41 and 42 in the plan view are increased, the influence on the size of the entire power module 1 is small, and thus, an interconnect resistance at the external terminals 41 and 42 can be reduced by increasing the areas of the external terminals 41 and 42 in the plan view. Further, because the external terminal 41 and the external terminal 42 are stacked by interposing the insulating film 50 therebetween, an inductance of the power module 1 can be significantly reduced.

In addition, the power module 1 can be manufactured mainly by successively stacking the respective members on the heat sink 30 and fastening the members with the male screws 60. Hence, an alignment of the members is facilitated, and the power module 1 can be manufactured with ease.

Moreover, because the protruding portion 66 is provided between the male screw 60 screwed into the heat sink 30 and the inner wall surface of the through hole 23, even in a case where the heat sink 30 is made of a metal, a high insulation can be achieved between the heat sink 30 and the semiconductor package 10.

### Second Embodiment

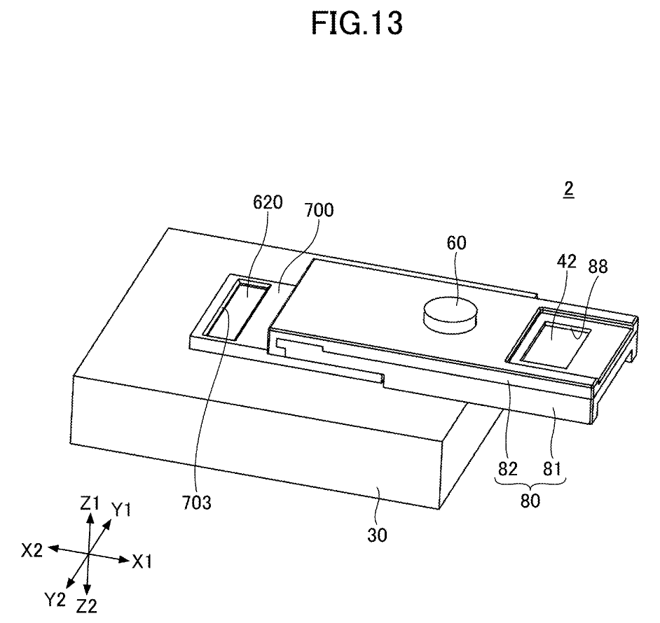

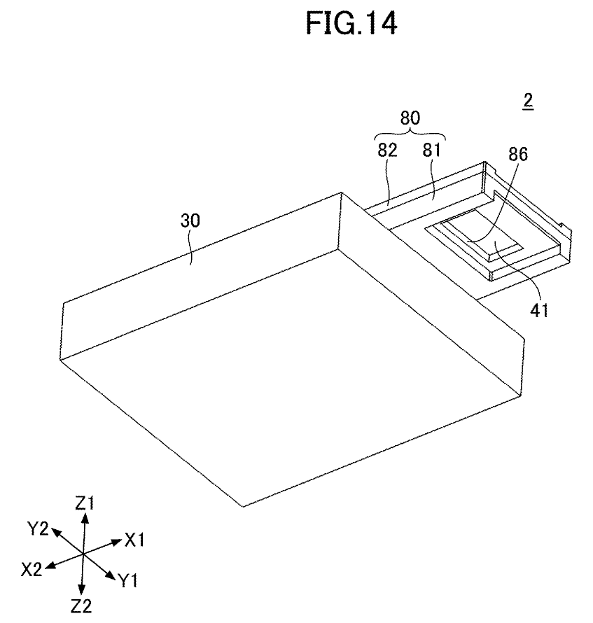

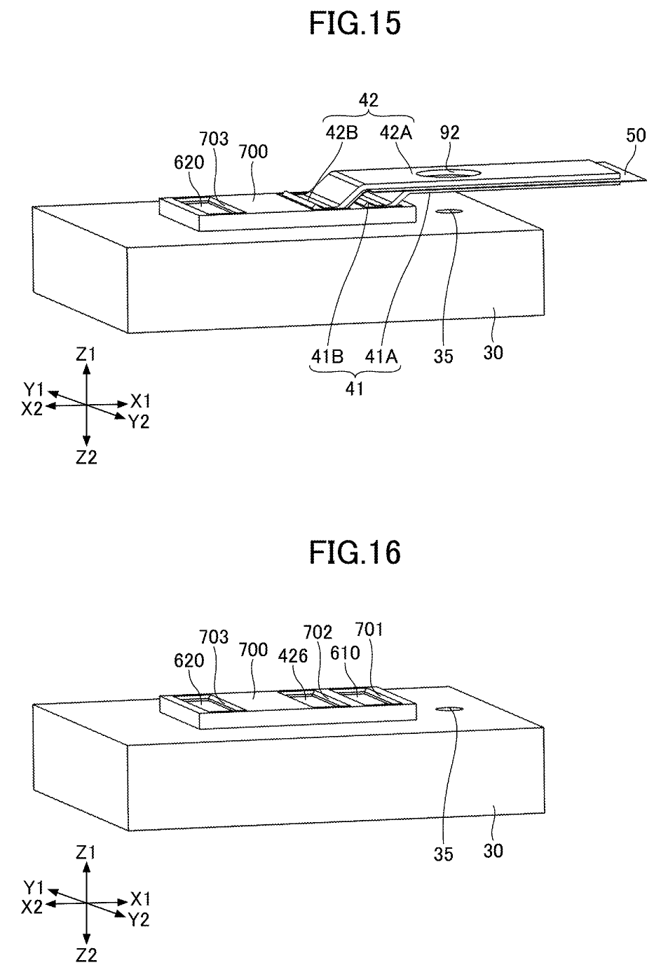

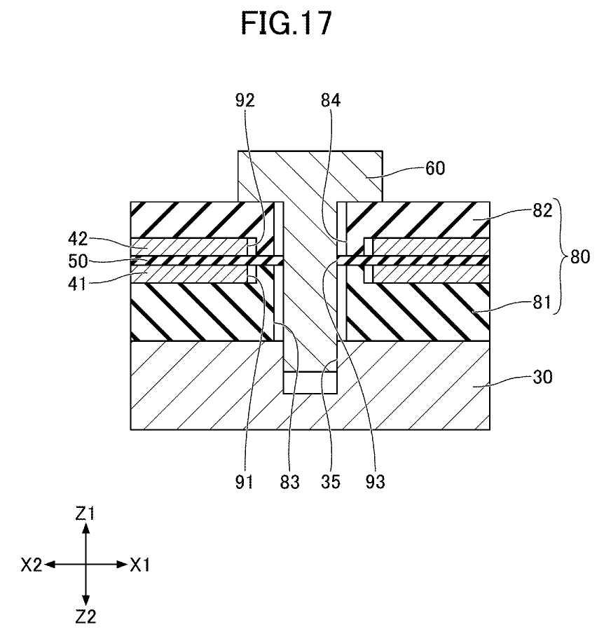

A second embodiment will be described. The second embodiment differs from the first embodiment mainly in the configurations of the lower case and the upper case. FIG. 13 and FIG. 14 are perspective views illustrating the entire power module according to the second embodiment. FIG. 15 and FIG. 16 are perspective views illustrating the power module according to the second embodiment. FIG. 17 is a cross sectional view schematically illustrating a part of the power module according to the second embodiment. In FIG. 13 through FIG. 17, the illustration of some of the constituent elements, such as the external terminal 43, the control terminal 71, the control terminal 72, or the like is omitted.

As illustrated in FIG. 13 through FIG. 17, a power module 2 according to the second embodiment includes a housing 80 in place of the housing 20. The number of the male screws 60 is one. The housing 80 includes a lower case 81 and an upper case 82.

As illustrated in FIG. 15, one hole 35 to be inserted with the male screw 60 is formed in the upper surface of the heat sink 30. The hole 35 is formed on the X1-side of the semiconductor package 10 in the plan view.

As illustrated in FIG. 13 and FIG. 14, the lower case 81 is provided on the heat sink 30 and the semiconductor package 10. The lower case 81 covers a part of the semiconductor package 10. The lower case 81 covers the openings 701 and 702 of the mold 700, but the opening 703 is exposed from the lower case 81.

As illustrated in FIG. 14, a stack of the flat plate portion 41A of the external terminal 41, the insulating film 50, and the flat plate portion 42A of the external terminal 42 is disposed on the lower case 81. The external terminal 41 is disposed on the lower case 81, the insulating film 50 is disposed on the external terminal 41, and the external terminal 42 is disposed on the insulating film 50. The stack of the flat plate portion 41A, the insulating film 50, and the flat plate portion 42A overlaps the hole 35 in the plan view.

The upper case 82 is provided on the lower case 81, and covers a part of the semiconductor package 10, the external terminals 41, 42, and 43, and the insulating film 50.

An opening 86 reaching the lower surface of the external terminal 41 is formed in the lower case 81, and an opening 88 reaching the lower surface of the external terminal 42 is formed in the upper case 82.

As illustrated in FIG. 17, a through hole 83 to be penetrated by the male screw 60 is formed in the lower case 81, and a through hole 84 to be penetrated by the male screw 60 is formed in the upper case 82. The through holes 83 and 84 connect to the hole 35 formed in the heat sink 30. For example, diameters of the through holes 83 and 84 are larger than the diameter of the hole 35. The diameter of the through hole 83 and the diameter of the through hole 84 may be substantially the same. Further, the external terminal 41 is formed with a through hole 91 to be penetrated by the male screw 60, the external terminal 43 is formed with a through hole 92 to be penetrated by the male screw 60, and the insulating film 50 is formed with a through hole 93 to be penetrated by the male screw 60. Diameters of the through holes 91 and 92 are larger than the diameters of the through holes 83 and 84, respectively. The diameter of the through hole 91 and the diameter of the through hole 92 may be substantially the same. The diameter of the through hole 93 is approximately the same as the diameter of the hole 35.

In the plan view, the through holes 84, 92, 93, 91, and 83 overlap the hole 35. For example, center axes of the through holes 84, 92, 93, 91, and 83 and the hole 35 coincide with one another. The male screw 60 penetrates the through holes 84, 92, 93, 91, and 83 and is screwed into the hole 35. The head of the male screw 60 is in contact with an upper surface of the upper case 82.

Although the illustration of the external terminal 43 is omitted, the external terminal 43 is provided outside the housing 80, and is not fixed to the housing 80.

Otherwise, the configuration of the power module 2 is the same as that of the power module 1.

According to the second embodiment, a compact power module 2 can be obtained. In addition, similar to the first embodiment, the interconnect resistance at the external terminals 41 and 42 can be reduced, and the inductance of the power module 2 can be significantly reduced. Further, the power module 2 can be manufactured with ease.

The number of the semiconductor devices 100 connected between the external terminal 41 and the external terminal 43 is not particularly limited, and the number of the semiconductor devices 200 connected between the external terminal 42 and the external terminal 43 is not particularly limited. For example, the number of the semiconductor devices 100 and 200 may be one or two. In addition, the insulating base material 411 and the insulating base material 421 may be integrated. In this case, the insulating base material in which the insulating base material 411 and the insulating base material 421 are integrated is an example of a first insulating base material, the first surfaces 413 and 423 are examples of a fifth surface, and the second surfaces 414 and 424 are examples of a sixth surface.

According to the disclosed technique, the power module can be downsized.

Although the embodiments are numbered with, for example, “first,” or “second,” the ordinal numbers do not imply priorities of the embodiments. Many other variations and modifications will be apparent to those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A power module comprising:
a first semiconductor device having a first surface and a second surface opposite to the first surface, a first electrode provided on the first surface, and a second electrode provided on the second surface;
a second semiconductor device having a third surface and a fourth surface opposite to the third surface, a third electrode provided on the third surface, and a fourth electrode provided on the fourth surface;
a first insulating base material having a fifth surface to which the first semiconductor device and the second semiconductor device are bonded, and a sixth surface opposite to the fifth surface;
a first conductive member penetrating the first insulating base material, electrically connected to the first electrode, and stacked on the sixth surface of the first insulating base material;
a second conductive member penetrating the first insulating base material, electrically connected to the third electrode, and stacked on the sixth surface of the first insulating base material;
a third conductive member electrically connected to the second electrode;
a fourth conductive member electrically connected to the fourth electrode;
a fifth conductive member electrically connecting the first conductive member and the fourth conductive member;
a first terminal electrically connected to the third conductive member;
a second terminal electrically connected to the second conductive member; and
an insulating film having a seventh surface facing the first terminal and an eighth surface facing the second terminal, wherein the insulating film is provided between the first terminal and the second terminal.

2. The power module as claimed in claim 1, wherein:
the first terminal makes contact with the seventh surface, and
the second terminal makes contact with the eighth surface.

3. The power module as claimed in claim 1, further comprising:
a heat dissipation member mounted with the first semiconductor device and the second semiconductor device;
a housing provided on the heat dissipation member, and configured to accommodate the first semiconductor device and the second semiconductor device and fix the first terminal and the second terminal; and
a fastening member configured to fasten the housing toward the heat dissipation member.

4. The power module as claimed in claim 3, wherein:
the housing includes a first case in contact with the heat dissipation member and the first terminal, and a second case in contact with the second terminal;
the first terminal, the insulating film, and the second terminal are successively arranged between the first case and the second case, and
the fastening member presses the second case toward the heat dissipation member.

5. The power module as claimed in claim 3, further comprising:
a third terminal electrically connected to the first conductive member, the fourth conductive member, and the fifth conductive member,
wherein the third terminal is fixed to the housing.

6. The power module as claimed in claim 3, further comprising:
a third terminal provided outside the housing and electrically connected to the first conductive member, the fourth conductive member, and the fifth conductive member.

7. The power module as claimed in claim 1, wherein:
the first insulating base material includes a second insulating base material and a third insulating base material,
the second insulating base material includes:
a ninth surface included in the fifth surface and bonded with the first semiconductor device, and
a tenth surface included in the sixth surface and stacked with the first conductive member; and
the third insulating base material includes:
an eleventh surface included in the fifth surface and bonded with the second semiconductor device, and
a twelfth surface included in the sixth surface and stacked with the second conductive member.
